(19) United States
(12) Patent Application Publication
(10) Pub. No.: US 2001/0038908 A1
(43) Pub. Date: Nov. 8, 2001

(54) Substrate for a planographic printing plate and substrate fabrication method

(76) Inventors: Masaya Matsuki, Shizuoka-ken (JP); Yoshinori Hotta, Shizuoka-ken (JP); Hirokazu Sawada, Shizuoka-ken (JP); Akio Uesugi, Shizuoka-ken (JP)

Correspondence Address: SUGHRUE, MION, ZINN, MACPEAK & SEAS, PLLC, Suite 800, 2100 Pennsylvania Avenue, N.W., Washington, DC, 20037-3213, US

(21) Appl. No.: 09/801,781

(22) Filed: Mar. 9, 2001

(30) Foreign Application Priority Data
Mar. 9, 2000 (JP) 2000-65155
Mar. 24, 2000 (JP) 2000-84856

(51) Int. Cl. B32B 3/00; B41N 1/06; C25D 11/16; C25F 3/04; G03F 7/09

(52) U.S. Cl. 428/221; 428/337; 430/302; 205/50; 205/153; 205/206; 205/214

(57) ABSTRACT

A substrate for a planographic printing plate and a method of fabrication thereof. After a surface roughening treatment and before an anodizing treatment, an aluminum alloy plate to be used as the substrate is washed in an alkali solution, and then in an acidic solution. After surface-roughening, overlap points of Fe and Si macularly distributed at the surface of the aluminum alloy plate have a surface coverage of not more than 0.5%, and there are no more than 800 per 1 mm² of overlap points which have sizes larger than 1.6×10⁻⁷ mm². The planographic printing plate of the present invention has excellent printing capabilities in that, irrespective of printing conditions, soiling does not occur at a non-image portion of the planographic printing plate.

### BACKGROUND OF THE INVENTION

1. Field of the Invention

The present invention relates to a substrate for a planographic printing plate having excellent printing characteristics and being free of the occurrence of staining at a non-image portion.

Further, the present invention relates to a method of fabricating a substrate for the planographic printing plate, particularly to a method of fabricating the same wherein the substrate is an aluminum alloy, which method can prevent the occurrence of excess ink staining at a printed image.

2. Description of the Related Art

Conventionally, a substrate for a planographic printing plate has been an aluminum plate whose raw material was either aluminum or an alloy whose principal component was aluminum (hereinafter referred to as “aluminum alloy”). A planographic printing plate precursor is fabricated by performing a surface roughening treatment on one or both surfaces of the aluminum plate and then coating the surface-roughened aluminum plate with a photosensitive layer. Often, in order to improve wear-resistance during printing, an anodization film treatment is performed on the surface-roughened surface(s) of the aluminum or aluminum alloy plate. Also, in order to shorten a vacuum contacting time during plate fabrication, microscopic protrusions and recesses, known as a “matt layer”, are provided at a surface of the photosensitive layer.

Plate fabrication processes such as exposure, development, rinsing and the like are performed on a planographic printing plate precursor to make a printing plate. Methods that can be used for image exposure include a method for applying a difference between an image portion and a non-image portion by contacting the precursor with a litho film onto which an image has been exposed and applying light, and a method for applying a difference between the image portion and the non-image portion by writing either the image portion or the non-image portion using an infrared laser, image projection or the like.

During development after image exposure, an undissolved portion of the photosensitive layer can form an image portion that receives ink, and a portion of the photosensitive layer that has been dissolved away to expose the aluminum surface or anodization film surface beneath the photosensitive layer forms a non-image portion that receives water. After development, a hydrophilizing treatment, gumming and, further, a burning treatment and the like may be performed as necessary.

The planographic printing plate is attached to a cylindrical plate roller in a printing press, to which ink and dampening water are supplied. The ink adheres to the lipophilic image portion and the water adheres to the hydrophilic non-image portion. The ink at the image portion transfers to a blanket roller, and the image is printed from the blanket roller onto paper. However, sometimes there may be a problem with ink adhering in spot shapes or ring shapes at the non- image portion, which results in the occurrence of spot or ring stains on the paper.

Many proposals have already been made as to how to prevent this excess ink staining. Specifically, methods that limit alloy components of the aluminum alloy that the aluminum plate is made from have been applied for. Methods that have been proposed include, for example, methods that specify contents of Mg, Mn, Si, Ga, Ti, Cu and the like to be included in the substrate (Japanese Patent Application Laid-Open (JP-A) Nos. 5-309964 and 3-177528), methods that limit a ratio of Fe and Si (JP-A Nos. 4-254545 and 7-197162), a method that limits a solution content of Fe (JP-A No. 4-165041), methods that limit a single amount of Si (JP-A Nos. 3-177529 and 62-148295), methods that limit quantity, size and distribution of intermetallic compounds (JP-A Nos. 4-165041, 3-234594, 4-254545 and 3-177529) and methods that limit characteristics of the anodization film (JP-A Nos. 7-197293 and 7-26393).

However, these are all methods that constrain the aluminum alloy, and are deficient in view of reducing freedom of selection of material for the aluminum plate that is the substrate for the planographic printing plate.

Materials that can be applied as the aluminum plate for the planographic printing plate substrate include Al—Mg alloys, Al—Mn alloys, Al—Mn—Mg alloys, Al—Zr alloys, Al—Mg—Si alloys and the like. These various alloys are usually produced by melting raw material with aluminum as the principal component thereof, adding predetermined additive elements to make an aluminum alloy melt with a standardized alloy composition, continuously carrying out a purification treatment on the aluminum alloy melt, and then casting. The purification treatment, to remove unwanted gases such as hydrogen and the like from the melt, is a flux treatment; a degassing treatment using Ar gas, Cl gas or the like; filtering using a “rigid media filter” such as a ceramic tube filter, a ceramic foam filter or the like, or a filter with alumina flakes or alumina balls as a filter medium, or a fiberglass cloth filter; or a treatment combining a degassing treatment and filtering. These purification processes are implemented to prevent defects that are caused by impurities such as non-metallic debris and oxides in the melt, and defects that are caused by gases penetrating the melt.

As general methods for casting the aluminum alloy melt that has been composition-controlled and purified as described above, there may be a method using a solid mold, as typified by a general DC casting method, or a method using a dynamic mold, as typified by a continuous casting method.

When a DC casting method is used, the aluminum alloy melt is solidified with a cooling rate of 1 to 300° C. per second. In this solidification process, the aforementioned alloy components form a solid solution in the aluminum. Alloy elements that do not form the solid solution occur in ingots as intermetallic compounds. An ingot of 300 to 800 mm plate thickness can be fabricated by the DC casting. Usually, facing machining, in which a surface layer portion is cut away, is performed on the ingot. A surface layer portion of thickness 1 to 30 mm, desirably 1 to 10 mm, is cut away from the ingot in the facing machining. Then a soaking treatment is performed on the ingot, if required. The soaking treatment changes unstable intermetallic compounds into more stable intermetallic compounds and forms a further portion of the intermetallic compounds into the solid solution in the aluminum.

Remaining intermetallic compounds can then be constricted and dispersed by a process that performs hot-rolling or cold-rolling. However, the nature of the intermetallic compounds is almost unchanged thereby. That is, there will still be intermetallic compounds in the aluminum plate for the planographic printing plate substrate. Moreover, a heat treatment, known as annealing, may be performed before, after or during the cold-rolling. In this case, the temperature of the annealing heat treatment may cause a portion of the solid solution in the aluminum to precipitate as deposits of intermetallic compounds and simple elements. These deposits will also remain in the aluminum plate.

The aluminum plate, when it has been rolled to a thickness of 0.1 to 0.5 mm by the cold-rolling, may be straightened to improve flatness thereof by a straightening device for improving flatness, such as a roller leveller, a tension roller or the like. When the aluminum plate has been finished to a predetermined shape in this manner, a surface roughening treatment and an anodizing treatment are performed on the surface of the aluminum plate.

The aluminum plate surface roughening method may be a mechanical graining method, an electrochemical graining method or a suitable combination thereof. Examples of the mechanical graining method include ball graining, wire graining, brush graining, a liquid honing method and the like. Alternating current electrolytic etching is generally selected as the electrochemical graining method. A usual sine wave alternating current or rectangular alternating current, or a particular alternating current or the like may be used as an electrolysis current. In addition, as a preliminary to this electrochemical graining, an etching treatment with caustic soda or the like may be performed on the aluminum plate.

Continuous application of an electrochemical graining system with a web has become widespread as a surface roughening method in recent years. However, when an aluminum plate is electrochemically grained in this manner, smuts, whose principal component is aluminum hydroxide, occur at the surface of the aluminum plate.

U.S. Pat. No. 4,548,683 discloses that with an alternating current having a high frequency, 140 to 400 Hz, homogeneous pits are formed and smuts tend not to form. However, apart from this particular case, smuts will form at the surfaces of aluminum plates that are electrochemically grained. Then the anodizing treatment and, in accordance with requirements, a silicate treatment, coating with a photosensitive material and drying are performed on the aluminum substrate that has been electrochemically grained, thereby producing a photosensitive printing plate precursor. If smuts remain at the surface of the aluminum plate after electrochemical graining, the smuts will contaminate the anodization film, and film defects and the like that occur will cause a deterioration in printing characteristics.

Japanese Patent Application Publication (JP-B) No. 56-11316 disclosed a desmutting method in which smuts occurring at an aluminum surface were dissolved and removed by contact with a 15 to 60% by weight solution of sulphuric acid whose temperature was regulated to 50 to 90° C. In addition, Japanese Patent No. 2,577,594 disclosed a desmutting method in which smuts occurring at a surface-roughened aluminum surface were first dissolved by an alkali solution with a pH of at least 10 and a temperature of 25 to 60° C., and then dissolved and removed in a solution whose principal component was sulphuric acid with a concentration of 50 to 400 g/liter and a temperature of 25 to 65° C., such that a dissolved amount of the basic aluminum was 0.03 to 0.20 g/m². In the former method, because use of an alkali solution was not incorporated, smut removal tended to be insufficient, and shape irregularities caused by electrolytic surface roughening were left at the aluminum surface, which reduced adhesion between the photosensitive layer and the aluminum plate, and caused problems with unsatisfactory printing characteristics such as print staining and the like. In the latter method, on the other hand, smuts caused by electrolytic surface roughening were effectively removed by the alkali solution. However, unwanted intermetallic compounds present at the surface of the aluminum plate could not be removed. Thus, there was a problem in that if aluminum alloy composition was not strictly controlled as described in aforementioned references, an ink staining characteristic deteriorated. Furthermore, because the temperature of the aluminum solution, at 25 to 60° C., was comparatively low, this dissolution treatment was slow, which was bad for productivity.

Further, it has been learned that a process of occurrence of stains at the non-image portion is extremely susceptible to influence from conditions during printing. In other words, whichever of the various above-described substrates and fabrication methods proposed as desirable are used, there will be cases in which staining at the non-image portion cannot be prevented, because of printing conditions. Planographic printing plates are currently in extremely wide use throughout the world, and printing conditions such as inks used and atmospheric temperatures are diverse. Therefore, a planographic printing plate substrate that, regardless of printing conditions, is not subject to staining at a non-image portion is desired.

### SUMMARY OF THE INVENTION

The object of the present invention is to provide a substrate for a planographic printing plate that has excellent printing characteristics and that, regardless of printing conditions, is not subject to staining at a non-image portion, and to provide a fabrication method of the substrate.

The inventors of the present invention studied substrates made from aluminum and aluminum alloys. With regard to a problem of ink adhering to the non-image portion in spots or ring shapes, and then causing spotted or ring-shaped ink stains on paper, the inventors discovered that surface intermetallic compounds could be removed by immersion in an aqueous solution of hydrochloric acid, and that occurrence of the ink stains could thereby be inhibited. The inventors proposed the same in Japanese Patent Application No. 11-362678. For clarification of this mechanism, the inventors examined aluminum samples with an electron probe micro-analyzer and discovered macular distributions of Fe and Si. The inventors also discovered a correlation between ink staining and the presence both of FeSi overlap points and of α-AlFeSi, which is an intermolecular compound including Fe and Si. Thus, the inventors accomplished the planographic printing plate substrate of the present invention.

Further, the inventors of the present application discerned that a cause of the ink staining was a portion of intermetallic compounds remaining at surfaces of aluminum plates fabricated by above-described processes. Consequently, the inventors discovered that by removing these stain-causing substances by surface treatment of an aluminum plate, and then using the aluminum plate as the substrate for the planographic printing plate, excess ink staining in the printed image could be effectively prevented. Then, the inventors considered a fabrication method for the planographic printing plate substrate. Consequently, the inventors discovered that, in accordance with the present invention, the substrate could be fabricated without management of aluminum alloy composition and of fabrication processes such as casting, rolling and the like being made more demanding than conventional management thereof.

That is, a planographic printing plate aluminum substrate of the present invention is an aluminum or aluminum alloy substrate whose surface has undergone a surface roughening treatment and an anodizing treatment. When the surface of the substrate is inspected using an electron probe micro-analyzer under below-described measuring conditions, overlap points of macularly distributed Fe and Si have a surface coverage of not more than 0.5%.

Measuring Conditions

Measuring instrument: electron probe micro-analyzer (EPMA); accelerating voltage: 20 kV; measurement current: 1.3×10⁻⁶ A; beam diameter: 0 μm; pixels: 425×425; interval: 0.4 μm (X)×0.4 μm (Y); measurement area: 170×170 μm². Under these conditions, specific count values for the macularly distributed Fe and Si (1630 for Fe and 137 for Si) were set as threshold values, and a binarizing treatment was performed.

Preferably, a surface coverage of macularly distributed Si is at most 0.6% when the surface of the substrate is inspected using the electron probe micro-analyzer under the above-described measuring conditions.

In one embodiment, the planographic printing plate aluminum substrate of the present invention is an aluminum or aluminum alloy substrate whose surface has undergone the surface roughening treatment and the anodizing treatment and then, when the surface of the substrate is inspected using the electron probe micro-analyzer under the same measuring conditions as above, overlap points of the macularly distributed Fe and Si that have sizes larger than 1.6×10⁻⁷ mm² number no more than 800 per 1 mm².

Substances that tend to lead to defect points in an anodization film are removed from the planographic printing plate substrate of the present invention. The surface coverage of overlap points of the macularly distributed Fe and Si is reduced, or there are fewer points having areas larger than a predetermined size. Thus, a good quality image portion having few anodization film defects can be obtained. Accordingly, homogeneous hydrophilic properties are achieved, and staining can be effectively prevented regardless of changes in printing conditions.

Furthermore, a preferable method of fabricating the planographic printing plate substrate of the present invention is a planographic printing plate substrate fabrication method in which a surface roughening treatment and an anodizing treatment are performed on an aluminum alloy. In this method, after the surface roughening treatment, the aluminum alloy is washed in an alkali solution having a pH of at least 10 and a temperature of 60 to 80° C. Then the aluminum alloy is washed in an acidic solution having an acid concentration of 170 to 800 g/liter as measured by neutralization titration and a temperature of 65 to 90° C. Then the anodizing treatment is performed on the surface of the surface-roughened aluminum alloy.

Further, by selecting sulphuric acid as the principal component of the acidic solution in the technique described above, the problematic intermetallic compounds at the surface of the aluminum alloy can be removed effectively. Moreover, in view of improving productivity, it is preferable if the temperature of the alkali solution is 65 to 80° C., the concentration of the acidic solution as measured by neutralization titration is 300 to 800 g/liter (if sulphuric acid is used, a concentration of sulphuric acid as measured by neutralization titration), and the temperature of the acidic solution is 70 to 90° C. In this case, treatment duration of the surface roughening treatment can be shortened.

### BRIEF DESCRIPTION OF THE DRAWINGS

FIG. 1A is an analytical view showing a distribution state of an aluminum substrate of Example 1 that has been mapped by an EPMA for an Fe-only part of a measurement range.

FIG. 1B is an analytical view showing a distribution state of the aluminum substrate of Example 1 that has been mapped by the EPMA for a Si-only part of the measurement range.

FIG. 1C is an analytical view showing a distribution state of FeSi overlap points of the aluminum substrate of Example 1 that has been mapped by the EPMA, at which overlap points Si and Fe overlap.

FIG. 2A is an analytical view showing a distribution state of an aluminum substrate of Comparative Example 1 that has been mapped by the EPMA for the Fe-only part of the measurement range.

FIG. 2B is an analytical view showing a distribution state of the aluminum substrate of Comparative Example 1 that has been mapped by the EPMA for the Si-only part of the measurement range.

FIG. 2C is an analytical view showing a distribution state of FeSi overlap points of the aluminum substrate of Comparative Example 1 that has been mapped by the EPMA, at which overlap points Si and Fe overlap.

### DESCRIPTION OF THE PREFERRED EMBODIMENTS

The present invention is explained in detail below.

In the present invention, aluminum or an aluminum alloy, which contains aluminum as a principal component and trace quantities of other elements, is used as a base material of a substrate for a planographic printing plate. Alloy plates containing trace quantities of other elements include alloy plates to which predetermined other elements have been loaded, alloy plates from which removing trace quantities of other elements is difficult, and the like. Such alloy plates contain 0.001 to 1.5% by weight of one or more elements selected from elements shown in the periodic table. Representative examples of other elements included in the aluminum alloy include silicon, iron, nickel, manganese, copper, magnesium, chromium, zinc, bismuth, titanium, vanadium and the like. Ordinarily, conventionally known raw materials as described in the fourth edition of The Aluminum Handbook (Published 1990, Japan Light Metal Association) or, if increased tensile strength is sought, an alloy of one of these wherein at most 5% by weight of magnesium is added can be used.

When the aluminum or aluminum alloy is formed into a flat plate, it is preferable to carry out a soaking treatment, an annealing treatment and the like, to homogenize structure and the like.

The aluminum or aluminum alloy plate formed in this way with a regulated thickness is subjected to predetermined surface treatments as described below. Thus, the substrate is obtained.

A surface roughening treatment applied to the aluminum or aluminum alloy is a combination of one or more of: a mechanical surface roughening treatment; a buffing treatment; a polishing treatment; a chemical etching treatment in an acidic or alkaline aqueous solution; an electrolytic polishing treatment in an acidic or alkaline aqueous solution; an electrolytic treatment in a neutral salt aqueous solution, with the aluminum plate serving as an anode or as a cathode; and an electrochemical surface roughening treatment using direct current or alternating current in an acidic aqueous solution. Particularly preferable examples of surface roughening processes include the following processes.

Specifically, a surface roughening method for an aluminum base material includes:

(a) a mechanical surface roughening process;

(b) a process of chemical etching in an acidic or alkaline aqueous solution, or a process of electrolytic polishing in an acidic or alkaline aqueous solution;

(c) a process of electrochemical surface roughening in an aqueous solution whose principal component is nitric acid; and

(d) a process of chemical etching in an acidic or alkaline aqueous solution, or a process of electrolytic graining in an acidic or alkaline aqueous solution.

Next, the aforementioned surface roughening processes are described in detail.

(a) The Mechanical Surface Roughening Process

The mechanical surface roughening treatment can form a surface having a center line average roughness (Ra) of 0.3 to 1.5 μm, at a lower cost than an electrochemical surface roughening process.

A mechanical surface roughening treatment wherein mechanical surface roughening is performed with rotating nylon brush rollers whose fiber diameters are 0.2 to 0.9 mm and with a slurry supplied to the aluminum plate surface is advantageous. Preferable well-known materials that can be used as an abrasive include silica sand, quartz, aluminum hydroxide, and mixtures thereof. Techniques are disclosed in detail in Japanese Patent Application Laid-Open (JP-A) No. 6-135175 and Japanese Patent Application Publication (JP-B) No. 50-40047. The slurry preferably has a specific gravity of 1.05 to 1.3. Techniques that may be used to apply the slurry include a spraying technique, a technique using a wire brush, a technique that transfers the slurry to the aluminum plate using surface formations of an indented pressure roller, and the like. Further techniques are disclosed in JP-A Nos. 55-074898, 61-162351 and 63-104889.

(b) The Process of Chemically Etching the Aluminum Plate in an Acidic or Alkaline Aqueous Solution, and the Process of Electrolytic Polishing in an Acidic or Alkaline Aqueous Solution

In order to remove stains, a natural surface oxidation film, rolling oil and the like, and to smooth off excessive bumps and indentations generated by the mechanical surface roughening process, 0.1 to 20 g/m², and preferably 5 to 20 g/m², of the aluminum or aluminum alloy is dissolved.

(b-1) The Process of Chemically Etching the Aluminum Plate in an Acidic or Alkaline Aqueous Solution

Acids that can be used in the acidic aqueous solution include phosphoric acid, nitric acid, sulphuric acid, chromic acid, hydrochloric acid, and mixed acids including two or more thereof. The concentration of the acidic aqueous solution is preferably 0.5 to 65% by weight. The solution temperature is preferably 30 to 95° C. and treatment duration is preferably 1 to 120 seconds. Sulphuric acid is particularly preferable for the acidic aqueous solution, and respective concentrations of the sulphuric acid and the aluminum are preferably selected from ranges such that crystallization does not occur at room temperature.

The concentration of the alkaline aqueous solution is preferably 1 to 30% by weight. An aqueous solution whose principal component is caustic soda is particularly preferable as the alkaline aqueous solution. Respective concentrations of the caustic soda and the aluminum are preferably selected from ranges such that crystallization does not occur at room temperature.

Particularly preferably, the concentration of the caustic soda is 4 to 6% by weight and a concentration of aluminum ions is 1 to 1.5% by weight, or the concentration of the caustic soda is 25 to 28% by weight and the concentration of aluminum ions is 5 to 9% by weight. The solution temperature is preferably 30 to 80° C. and treatment duration is preferably 0.1 to 60 seconds.

Preferably, when the etching treatment has finished, nipping rollers remove the solution and a spray performs washing, such that the treatment solution is not carried on to the next process.

When the alkaline aqueous solution is used for the chemical etching, smuts commonly occur on the surface of the aluminum. Therefore, a desmutting treatment is carried out with phosphoric acid, nitric acid, sulphuric acid, chromic acid, hydrochloric acid, or a mixed acid including two or more thereof. Concentration of this acidic aqueous solution is preferably 0.5 to 60% by weight. From 0 to 5% by weight of aluminum and, of course, other components included in the aluminum alloy may be dissolved in the acidic aqueous solution. The solution temperature is preferably maintained from room temperature to 95° C. and treatment duration is preferably 1 to 60 seconds. Preferably, when the desmutting treatment has finished, nipping rollers remove the solution and a spray performs washing, such that this treatment solution is not carried on to the next process.

The desmutting treatment in the acidic aqueous solution is most preferably carried out with an aqueous solution at 15 to 50° C. containing 0.5 to 3% by weight of hydrochloric acid or nitric acid and 0 to 1% by weight of aluminum ions, or an aqueous solution at 15 to 70° C. containing 5 to 30% by weight of sulphuric acid and 0 to 1% by weight of aluminum ions.

(b-2) The Process of Electrolytic Treatment in an Acidic or Alkaline Aqueous Solution

Electrolytic Polishing Treatment in an Acidic Aqueous Solution

An aqueous solution used in well-known electrolytic polishing can be used in the electrolytic polishing in an acidic aqueous solution treatment of the present invention. An aqueous solution whose principal component is sulphuric acid or phosphoric acid is preferable. An aqueous solution containing 20 to 90% by weight (preferably 40 to 80% by weight) of sulphuric acid or phosphoric acid is particularly preferable. The solution temperature can be selected from a range of 10 to 90° C. (preferably 50 to 80° C.), current density can be selected from a range of 1 to 200 A/dm² (preferably 5 to 80 A/dm²) and treatment duration can be selected from a range of 1 to 180 seconds. To the aqueous solution may be added 1 to 50% by weight of sulphuric acid, phosphoric acid, chromic acid, hydrogen peroxide, citric acid, boric acid, hydrofluoric acid, phthalic anhydride or the like. The aqueous solution may also contain 0 to 10% by weight of aluminum and, of course, other components included in the aluminum alloy. Preferably, concentration of sulphuric acid ions or phosphoric acid ions and concentration of aluminum ions are such that crystallization does not occur at room temperature.

Electrolytic Polishing Treatment in an Alkaline Aqueous Solution

The electrolytic polishing in an alkaline aqueous solution treatment of the present invention is an electrolysis treatment wherein the aluminum is an anode in an electrolyte whose composition temperature and concentration are such that the electrolyte is a deoxidizing material. The aqueous solution used in this electrolysis treatment may contain a single alkaline material such as sodium hydroxide, potassium hydroxide, sodium carbonate or sodium phosphate; a mixture thereof; a mixture of alkaline material with zinc hydroxide or aluminum hydroxide; or a mixture of alkaline material with a salt such as sodium chloride, potassium chloride or the like. In order to produce a uniform oxidation film stably, hydrogen peroxide, a phosphate or the like may be added at a concentration of not more than 1% by weight. An aqueous solution used in well-known electrolytic polishing can be used, but the principal component of the aqueous solution is preferably sodium hydroxide. The aqueous solution preferably contains 2 to 30% by weight of sodium hydroxide and particularly preferably contains 3 to 20% by weight of sodium hydroxide. The solution temperature can be selected from a range of 10 to 90° C. (preferably 35 to 60° C.), current density can be selected from a range of 1 to 200 A/dm² (preferably 20 to 80 A/dm²) and treatment duration can be selected from a range of 1 to 180 seconds.

In the electrolytic polishing in an acidic or alkaline aqueous solution treatment, a direct current, a pulse current or an alternating current can be used. However, a continuous direct current is preferable. A flat tank, a radial tank or the like, as used in well-known electrolytic treatments, can be used as an electrolytic treatment apparatus. Preferably, when the treatment has finished, nipping rollers remove the solution and a spray performs washing, such that the treatment solution is not carried on to the next process. Further, chemical etching is preferably performed to dissolve 0.01 to 3 g/ m² of the aluminum or aluminum alloy in an acidic or alkaline aqueous solution before, after, or both before and after the electrolytic polishing treatment.

(c) The Process of Electrochemical Surface Roughening in an Aqueous Solution whose Principal Component is Nitric Acid

This process is performed in order to produce craters or honeycomb pits with an average diameter of 0.1 to 20 μm over from 30 to 100% of the area of the surface of the aluminum or aluminum alloy. The effect thereof is to improve stain resistance and printing resistance of a non-image portion of the printing plate.

An aqueous solution that is used in a usual electrochemical surface roughening treatment that utilizes direct current or alternating current can be used as the “aqueous solution whose principal component is nitric acid” of the present invention. An aqueous solution of nitric acid whose concentration is 5 to 20 g/liter can be used. At least one hydrochloride compound containing hydrochloride ions, such as aluminum chloride, sodium chloride, ammonium chloride and the like, or nitrate compound containing nitrate ions, such as aluminum nitrate, sodium nitrate, ammonium nitrate and the like, can be added to the aqueous solution in an amount of from 1 g/liter to a saturation amount. Metals included in the aluminum alloy, such as iron, copper, manganese, nickel, titanium, magnesium, silica and the like, may be dissolved in the aqueous solution whose principal component is nitric acid. An aqueous solution of 5 to 20 g/liter of nitric acid, to which aluminum chloride or aluminum nitrate has been added such that there is 3 to 50 g/liter of aluminum ions in the aqueous solution, is particularly preferably used. The temperature thereof is preferably 10 to 95° C. and more preferably 40 to 80° C.

This surface roughening can be performed with an alternating current.

An alternating current power supply waveform used for the electrochemical surface roughening can be a sine wave, a rectangular wave, a trapezoid wave, a triangular wave or the like. A rectangular wave or a trapezoid wave is preferable, and a trapezoid wave is particularly preferable. Frequency is preferably 0.1 to 250 Hz. With a trapezoid wave, a time tp in which the current goes from 0 to a peak value is preferably 0.1 to 10 ms and particularly preferably 0.3 to 2 ms. If tp is less than 0.1 ms, a large power supply voltage will be required during a rise of the waveform, because of the effect of impedance of a power supply circuit, and the cost of power supply equipment will be high. If tp is more than 10 ms, the process will be susceptible to the effect of trace components in the electrolyte and it will be difficult to perform surface roughening homogeneously.

At the moment that the electrochemical surface roughening finishes, a total quantity of electricity active in an anode reaction at the aluminum plate is preferably 1 to 1000 C/dm², and further preferably 10 to 300 C/dm². The larger the quantity of electricity, the greater the surface roughness. A power supply waveform used in the electrochemical surface roughening can be a direct current or an alternating current. An electrolytic bath used in the electrochemical surface roughening of the present invention with an alternating current can be an electrolytic bath used for well-known surface treatments such as a flat bath, a longitudinal bath, a radial bath or the like. A radial electrolytic bath as disclosed in JP-A No. 5-195300 is particularly preferable. Electrolyte passing through the interior of the electrolytic bath may run parallel with or counter to a direction of travel of an aluminum web. One or more alternating current power supplies can be connected to one electrolytic bath. Also, two or more electrolytic baths can be used.

(d) The Process of Chemical Etching in an Acidic or Alkaline Aqueous Solution, or the Process of Electrolytic Graining in an Acidic or Alkaline Aqueous Solution

This process is performed in order to remove smut compositions, whose principal component is aluminum hydroxide produced by the electrochemical surface roughening treatment, and to smooth off edge parts of pits. An amount of the aluminum plate which is dissolved in this process is preferably 0.01 to 20 g/m², more preferably 0.05 to 5 g/m², and further preferably 0.1 to 3 g/m².

Conditions of either process are the same as in processes (b-1) and (b-2) of process (b).

Next, a washing treatment with an alkaline solution is performed on the aluminum plate that has been electrolytically roughened as described above, as part of a desmutting treatment to remove smuts generated by the surface roughening processes. Smuts on the surface are dissolved and removed. At the same time, bumps and indentations generated at the surface by the surface roughening are partially dissolved. Thus, the form of the surface can be prepared. The alkaline solution can be any of a variety of alkaline solutions such as caustic soda and the like. In the present invention, the aluminum plate is treated with an alkaline solution having a pH of at least 10 and a temperature of 60 to 80° C. At this time, in view of improving productivity, the temperature of the alkaline solution is controlled within the range 65 to 80° C. Consequently, treatment of the aluminum plate with the alkaline solution can be completed in an extremely short time, 1 to 10 seconds. An immersion technique, a spray technique, a method that coats the aluminum plate with the solution, or the like can be selected for washing with the alkaline solution.

Next, the aluminum plate is treated with an acidic solution. The principal component of the acidic solution is preferably sulphuric acid. The concentration of the solution (concentration of sulphuric acid as determined by neutralization titration) is set to be 170 to 800 g/liter. If the concentration of sulphuric acid as determined by neutralization titration is less than 170 g/liter, the smuts will be removed but particles of intermetallic compounds will not be very effectively removed. Consequently, a concentration in the range 300 to 800 g/liter is preferable. Further, temperature of the acidic solution must be 65 to 90° C. At this time, in comparison with the acid concentration as determined by neutralization titration (that is, if sulphuric acid is being used, the concentration of sulphuric acid as determined by neutralization titration), the temperature of the acidic solution has a greater effect on the effectiveness with which the particles of intermetallic compounds are removed. If the temperature is less than 65° C., the particles of intermetallic compounds will not be effectively removed. Particularly, in view of productivity, the temperature of the acid solution is preferably 70 to 90° C., such that the particles of intermetallic compounds can be removed in a short time, and further preferably 80 to 90° C. An immersion technique, a spray technique, a method that coats the aluminum plate with the solution, or the like can be selected for washing with the acidic solution.

In accordance with the above-described planographic printing plate substrate fabrication method, prior to an aforementioned anodizing treatment, the aluminum plate is sequentially washed under predetermined conditions with an alkaline solution and an acidic solution. Thus, problematic particles of intermetallic compounds and smuts occurring at the surface of the aluminum plate can be removed. Consequently, defects in an anodization film that are caused by smuts and intermetallic compounds in the anodizing treatment of the surface of the aluminum plate do not occur. Therefore, the aluminum plate can be fabricated without strict control of fabrication processes and of the composition of the aluminum alloy. As a result, when the aluminum plate fabricated by the planographic printing plate substrate fabrication method of the present embodiment is a substrate for fabrication of a planographic printing plate, printing by the planographic printing plate of excess ink stains at a non-image portion is effectively prevented.

Provided the anodization film of the aluminum plate relating to the present embodiment is intrinsically stable, a hydrophilic property thereof will be sufficiently high. Therefore, a photosensitive film can be formed by directly coating a photosensitive material onto the anodization film. Other surface treatments can be implemented as necessary. For example, a silicate layer formed of an alkali metal silicate, and an undercoat layer formed of hydrophilic polymer molecules can be provided on the surface of the aluminum plate. A coating amount of such an undercoat layer is preferably 1 to 150 mg/m². Hence, the photosensitive film is formed on the aluminum plate which has, as necessary, been provided with the undercoat layer. Thus, a planographic printing plate precursor is fabricated. This planographic printing plate precursor is subjected to image exposure and development processes to be made into a planographic printing plate, and is then set in a printing press.

One possible and preferable treatment method for obtaining the planographic printing plate substrate of the present invention is a method which was suggested by the inventors of the present invention in Japanese Patent Application No. 11-362678. In this method, after the aforementioned surface roughening treatment, a chemical treatment is performed in an aqueous solution containing hydrochloric acid.

The object of performing this treatment is to remove substances that cause ink staining from the surface-roughened aluminum surface before the anodization film is applied.

Concentration of the hydrochloric acid may be 1 to 5% by weight. Treatment duration may be 10 seconds to 3 minutes and is desirably 30 seconds to 3 minutes.

Then, desirably, a desmutting treatment is performed in which smut components are removed by immersion in an aqueous solution whose principal component is sulphuric acid or nitric acid. The desmutting treatment is preferably performed by an aqueous solution whose principal component is sulphuric acid, with a temperature of at least 30° C. and more preferably 40 to 60° C., for a duration of at least 20 seconds and more preferably 30 to 60 seconds.

Then, in order to obtain the substrate of the present invention, an anodizing treatment is performed with the objective of raising abrasion resistance of the surface of the aluminum or aluminum alloy. An electrolyte used in the anodizing treatment of the aluminum plate can be anything that will form a porous anodization film. In general, sulphuric acid, phosphoric acid, oxalic acid, chromic acid, or a mixture thereof can be used. Concentration of the electrolyte is suitably determined in accordance with the type of electrolyte. Because conditions for the anodizing treatment vary in accordance with the type of electrolyte, the conditions cannot be unconditionally specified for all cases. However, in general, appropriate ranges are a concentration of the electrolyte of 1 to 80% by weight, a temperature of 5 to 70° C., a current density of 1 to 60 A/dm², a voltage of 1 to 100 V and an electrolysis duration of 10 to 300 seconds.

Anodizing treatments in aqueous solutions of sulphuric acid are described in detail in JP-A Nos. 54-12853 and 48-45303. A sulphuric acid concentration of 10 to 300 g/liter and an aluminum concentration of 1 to 25 g/liter are preferable. A 50 to 200 g/liter aqueous solution of sulphuric acid with aluminum sulfate added to give an aluminum ion concentration of 2 to 10 g/liter is particularly preferable. Temperature of the solution is preferably 30 to 60° C. If a direct current method is utilized, current density is preferably 1 to 60 A/dm² and particularly preferably 5 to 40 A/dm². If an aluminum sheet is being anodized in a continuous manner, in order to prevent current concentrations (referred to as burns) at the aluminum or aluminum alloy, it is particularly preferable if the anodizing treatment is performed initially at a low current density of 5 to 10 A/dm², in the latter half of the process gradually increasing to and thereafter being fixed at 30 to 40 A/dm².

In a method utilizing sulphuric acid, processing is usually done with direct current, but alternating current can also be used. A range of 1 to 10 g/m² is suitable for the amount of the anodization film. In the case of an ordinary planographic printing plate, an anodization film amount of 1 to 5 g/m² is suitable. If the amount is less than 1 g/m², printing resistance will be insufficient, the non-image portion of the planographic printing plate will be vulnerable to damage, and ink will adhere to damaged areas such that stains known as damage stains will tend to occur. Further, if the anodization film amount is large, the anodization film will tend to concentrate at edge areas of the aluminum or aluminum alloy. Thus, it is preferable if a difference between anodization film amounts at edge areas and at central areas is not more than 1 g/m².

The surface of the substrate obtained in accordance with the disclosure of the present invention was examined with the measuring method described below, using an electron probe micro-analyzer (EPMA).

Method of Evaluation by EPMA Mapping

Measurement Device:

Electron probe micro-analyzer (manufacturer: JEOL Ltd., trade name: JXA-8800M)

Measurement Conditions:

Accelerating voltage: 20 kV

Measurement current: 1.3×10⁻⁶ A

Beam diameter: 0 μm (electron beam in focussed state)

Pixels: 425×425

Interval: 0.4 μm (X)×0.4 μm (Y)

Measurement Area:

170×170 μm²

Here, a trend of points at which Fe and Si overlap (hereinafter referred to as “FeSi overlap points” where appropriate) was used as an index for an α-AlFeSi distribution condition. It was considered that defects would tend not to occur at the surface if there were few defect-originating points in the anodization film, which would be the case if there were few FeSi overlap points, or if a surface area coverage of FeSi overlap points was not more than 0.5% and a surface area coverage of Si-only parts was not more than 0.6%. It was understood that in this case ink staining at non-image areas would be less likely to occur.

The photosensitive layer is coated onto the substrate of the present invention, manufactured as described above with preferable conditions satisfied. Thus, the planographic printing plate precursor is obtained.

A conventionally known composition can be used as appropriate for an image-formation layer. As specific representative examples of positive-type heat-sensitive compositions, resins that are soluble in alkaline aqueous solutions and that have phenolic hydroxyl groups, such as novolak and the like, can be used. For example JP-A No. 7-285275 proposes an image-forming material in which a material that absorbs light and generates heat, and various onium salts, quinone diazide compounds and the like are added to an alkaline aqueous solution-soluble resin having a phenolic hydroxyl group, such as novolak or the like. In this image-forming material, the onium salts, quinone diazide compounds and the like act as dissolution inhibitors for the alkaline aqueous solution-soluble resin at image areas. The image-forming material is decomposed by heat and does not express inhibitance at non-image areas. The image-forming material is removed by development and an image is formed. In the planographic printing plate of the present invention, a protective layer may be provided on the image-forming layer, in accordance with requirements. Examples of components of the protective layer include polyvinyl alcohol, matt materials that are usually used in photosensitive image-forming materials, and the like.

Other photopolymeric photosensitive layers and the like may be used without problems.

Formulas of image-forming materials that are suitable for the substrate of the present invention and that had no problems when evaluated are shown below.

Photosensitive layer coating solution (a)

| | |
|---|---|
| Carbon black dispersion solution | 10 g |
| 4-diazodiphenylamine and formaldehyde-condensed | 0.5 g |
| hexafluoride phosphate | |
| Copolymer of methacrylate, 2-hydroxyethylacrylate, | 5 g |
| benzil methacrylate and acrylonitrile radicals (mole ratio: | |
| 15:30:40:15, weight-average molecular weight 100,000) | |
| Malic acid | 0.05 g |
| Fluorosurfactant (trade name: FC-430, produced by 3 M) | 0.05 g |
| 1-methoxy-2-propanol | 80 g |
| Lactic ethyl | 15 g |
| Water | 5 g |

Photosensitive layer coating solution (b)

| | |
|---|---|
| Capric acid | 0.03 g |
| Specific copolymer (a copolymer containing at least one | 0.75 g |
| of a resin having a phenolic hydroxyl group, a monomer | |
| having a sulfonamide group and a monomer having an | |
| active imino group as a copolymer component with a | |
| mole percentage of at least 10%) | |
| m,p-cresol novolak (m:p ratio = 6:4) | 0.25 g |
| p-toluenesulfonic acid | 0.003 g |
| Tetrahydrophthalic anhydride | 0.03 g |
| Cyanine dye | 0.017 g |
| VICTORIA PURE BLUE BOH dye with 1-naphthalene | 0.017 g |
| sulfonate anions as counter-ions | |
| Fluorosurfactant (trade name: MEGAFAC F-177, | 0.05 g |
| produced by Dainippon Ink & Chemicals, Inc.) | |
| γ-butyl lactone | 10 g |
| Methyl ethyl ketone | 10 g |
| 1-methoxy-2-propanol | 1 g |

Photosensitive layer coating solution (c)

| | |
|---|---|
| Capric acid | 0.03 g |
| m,p-cresol novolak (m:p ratio = 6:4) | 1 g |
| p-toluenesulfonic acid | 0.003 g |
| Tetrahydrophthalic anhydride | 0.03 g |
| Cyanine dye | 0.017 g |
| VICTORIA PURE BLUE BOH dye with 1-naphthalene | 0.017 g |
| sulfonate anions as counter-ions | |
| Fluorosurfactant (trade name: MEGAFAC F-177, | 0.05 g |
| produced by Dainippon Ink & Chemicals, Inc.) | |
| γ-butyl lactone | 10 g |
| Methyl ethyl ketone | 10 g |
| 1-methoxy-2-propanol | 1 g |

Photosensitive layer coating solution (d)

| | |
|---|---|
| Photopolymer photosensitive solution | |
| Tetra methylol methane tetraacrylate | 1.5 g |
| Linear organic macromolecule polymer (B1) (structure | 2.0 g |
| below) | |
| Sensitizer (C1) (structure below) | 0.15 g |
| (λmax THF 479 nm, ε = 6.9 × 10⁴) | |
| Photoinitiator (D1) (structure below) | 0.2 g |
| Photopolymerization initiator (trade name: IRGACURE | 0.4 g |
| 907, produced by Ciba-Geigy AG) | |
| ε-phthalocyanine/dispersion solution of (B1) | 0.2 g |
| Flourine-containing nonionic surfactant (trade name: | 0.03 g |
| MEGAFAC F-177, produced by Dainippon Ink & | |
| Chemicals, Inc.) | |
| Methyl ethyl ketone | 9 g |
| Propylene glycol monomethyl ether acetate | 7.5 g |
| Toluene | 11 g |
| As a photopolymerization initiator, a titanium compound (trade | |
| name: CGI 784, produced by Ciba-Geigy AG) is also available. | |
| Oxygen barrier layer | 11 g |
| 3% by weight aqueous solution of polyvinyl alcohol | |
| (saponification: 98 mole %, polymerization: 500) | |

| | |
|---|---|
| | (B1) |
| 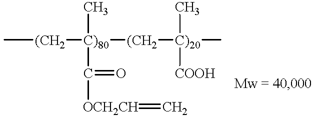 | |
| | (C1) |
| 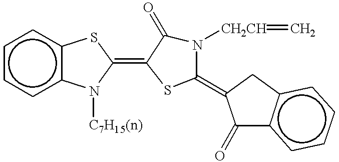 | |
| | (D1) |
| 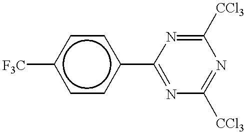 | |

Photosensitive layer coating solution (e)

| Polymerizing layer coating solution | |
|---|---|
| Pentaerithrytol tetraacrylate | 2.5 g |
| 20% by weight propylene glycol monomethyl ether | 37.5 g |
| solution of a copolymer of allyl methacrylate and | |
| methacrylic acid (copolymer ratio = 80:20) | |
| Pigment dispersion solution | 13.0 g |
| Methyl ethyl ketone | 74.0 g |
| Photosensitive layer coating solution (applied after drying of | |
| the polymerizing layer coating) | |
| 10% by weight aqueous solution of 79.5% saponified | 10.5 g |
| polyvinyl alcohol (trade name: PVA-405, produced | |
| by Kuraray Co., Ltd.) | |
| 0.11% by weight methanol solution of additive (SH-1) | 0.41 g |
| shown below | |
| 0.11% by weight aqueous solution of additive (SH-2) | 0.41 g |
| shown below | |
| Silver halide emulsion, described below | 0.50 g |
| 5% by weight aqueous solution of surfactant (SA-1) | 0.40 g |
| shown below | |
| Water | 7.80 g |
| Reducer dispersion solution | 1.20 g |
| Oxygen barrier layer (applied after drying of the photosensitive | |
| layer coating) | |
| 10% by weight aqueous solution of 98.5% saponified | 200.0 g |
| polyvinyl alcohol (trade name: PVA-105, produced | |
| by Kuraray Co., Ltd.) | |
| Base precursor dispersion solution, shown below | 1.25 g |
| Surfactant aqueous solution | 4.0 g |
| | (SH-1) |
| 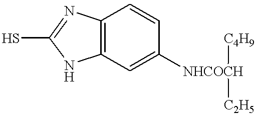 | |
| | (SH-2) |
| 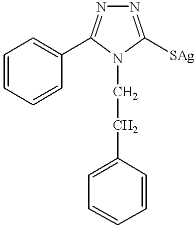 | |
| | (SA-1) |
| 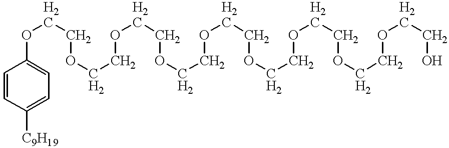 | |
| (Base precursor) | |
| 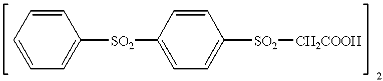 | |
| 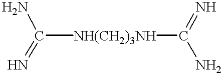 | |

Photosensitive layer coating solution (f)

| | |
|---|---|
| Resin layer | |
| Acetone-pyrogallol solution resin: | 5.0 g |
| naphthoquinone-1,2-diazide-(2)-5-sulfonate | |
| Cresol-formaldehyde resin | 10.0 g |
| Methyl ethyl ketone | 150 g |
| Cyclohexane | 122 g |
| Photosensitive layer (applied after drying of the resin layer | |
| coating) | |
| Silver chlorobromide gelatin emulsion (Cl: 70 mole %; | 1000 g |
| Br: 30 mole %; average particle diameter: 0.28 μm; | |
| gelatin amount per 1 kg of emulsion: 55 g; silver halide | |
| content: 0.85 mole) | |
| 0.1% methanol solution of 1,3-diethyl-5-[2-(3-(3- | 50 ml |
| sulfopropyl)benzoxazol-2-ylidene)ethylidene] | |
| thiohydantoin sodium salt | |
| 0.5% alkaline aqueous solution of | 100 ml |
| 4-hydroxy-6-methyl 1,3,3a,7-tetrazinedene | |
| 2% aqueous solution of | 35 ml |
| 2,4-dichloro-6-hydroxy-s-triazine | |

Photosensitive layer coating solution (g)

| Physical development center layer | |
|---|---|
| A silver sol prepared by the Carey Lea method is coated such | |
| that a dry weight amount of silver is 5 mg/m². | |
| Silver halide layer | |
| A silver chlorobromide emulsion composed of 40 mole % | |
| chloride and 60 mole % bromide and having an average particle | |
| size of 0.3 μm is coated at 2.0 g/m² (silver:gelatin weight | |
| ratio = 1:1). | |
| | (parts |
| | by |
| | weight) |

Photosensitive layer coating solution (h)

| | |
|---|---|
| Coating solution for photoconduction layer | |
| Non-metallic phthalocyanine (trade name: FASTOGEN | 1.0 |
| BLUE 8120, produced by Dainippon Ink & Chemicals, Inc.) | |
| Copolymer of methyl methacrylate and methacrylic acid | 10.0 |
| (methacrylic acid: 20 mole %) | |
| Tetrahydrofuran | 60 |
| Cyclohexane | 40 |
| Coating solution for protective layer | |
| Polyvinyl butyral (trade name: 2000-L, produced by | 2.0 |
| Denki Kagaku Kogyo K. K.) | |
| Stearic acid | 0.5 |
| Ethanol | 97.5 |

Photosensitive layer coating solution (i)

| | |
|---|---|
| A high molecular compound having, at a side chain, a | 1.0 g |
| functional group that generates sulfonic acid by the action | |
| of acid (compound disclosed in JP-A 10-207068) | |
| o-naphthoquinone diazide-4-sulfonic chloride | 0.1 g |
| VICTORIA PURE BLUE BOH dye with 1-naphthalene | 0.05 g |
| sulfonate as counter-ions | |
| Fluorosurfactant (trade name: MEGAFAC F-176PF, | 0.06 g |
| produced by Dainippon Ink & Chemicals, Inc.) | |
| Methyl ethyl ketone | 10 g |
| γ-butyrolactone | 10 g |
| Photosensitive layer coating solution (j) | |

Exposed silver thin film photosensitive layer, prepared using method disclosed in JP-A 11-139023.

It can be seen that the substrate of the present invention can be applied with any of the above-described variety of photosensitive materials and any of various image-forming devices to provide a planographic printing plate substrate that, regardless of conditions of a photosensitive layer, provides good printed matter without causing staining at the non-image portion and has excellent printing characteristics.

The planographic printing plate substrate of the present invention controls a range of occurrence of the FeSi overlap points that cause defects to occur in the anodization film. Therefore, irrespective of printing conditions such as external conditions, type of photosensitive layer used, printing ink, composition of dampening water and the like, the planographic printing plate substrate realizes excellent printing characteristics without staining of the non-image portion.

### EXAMPLES

Below, the present invention is concretely explained by Examples. The present invention is not limited to these Examples.

### Examples 1 to 6, Comparative Examples 1 to 4

In accordance with the procedures described below, Examples and Comparative Examples of substrates were fabricated with various combinations of compositions, refinements and hydrochloric acid aqueous solution treatments of aluminum alloys. Types, compositions, materials and hydrochloric acid aquaous solution treatments of the aluminum alloys that were used are shown in Table 1 below.

TABLE 1

| | | | | | | | | | | | Hydro- |
|---|---|---|---|---|---|---|---|---|---|---|---|
| | Alloy | | | | | | | | | | chloric acid |
| | material | Alloy composition (wt %) | | | | | | | | | treatment |
| | (JIS A) | Fe | Si | Cu | Ti | Mn | Mg | Zn | Others | material | performed? |
| Example 1 | 1050 | 0.32 | 0.07 | 0.015 | 0.03 | 0.001 | 0.001 | 0.001 | (*) | H18 | Yes |
| Comparative | 1050 | 0.32 | 0.07 | 0.015 | 0.03 | 0.001 | 0.001 | 0.001 | (*) | H18 | No |
| Example 1 | | | | | | | | | | | |
| Example 2 | 1050 | 0.23 | 0.10 | 0.015 | 0.03 | 0.001 | 0.001 | 0.001 | (*) | H18 | No |
| Example 3 | 1050 | 0.23 | 0.04 | 0.015 | 0.03 | 0.001 | 0.001 | 0.001 | (*) | H18 | No |
| Example 4 | 1050 | 0.30 | 0.08 | 0.015 | 0.03 | 0.001 | 0.001 | 0.001 | (*) | O | Yes |
| Comparative | 1050 | 0.30 | 0.08 | 0.015 | 0.03 | 0.001 | 0.001 | 0.001 | (*) | O | No |
| Example 2 | | | | | | | | | | | |
| Example 5 | 3005 | 0.50 | 0.40 | 0.3 | 0.1 | 1.2 | 0.4 | 0.25 | (*) | H18 | Yes |
| Comparative | 3005 | 0.50 | 0.40 | 0.3 | 0.1 | 1.2 | 0.4 | 0.25 | (*) | H18 | No |
| Example 3 | | | | | | | | | | | |
| Example 6 | 3005 | 0.48 | 0.37 | 0.3 | 0.1 | 1.2 | 0.4 | 0.25 | (*) | O | Yes |
| Comparative | 3005 | 0.48 | 0.37 | 0.3 | 0.1 | 1.2 | 0.4 | 0.25 | (*) | O | No |
| Example 4 | | | | | | | | | | | |

(*) Aluminum and other unavoidable impurities

(1) Mechanical Roughening

An abrasive slurry was a suspension of pumice and water having a specific gravity of 1.12. An aluminum plate was an aluminum substrate of thickness 0.24 mm and width 1030 mm selected from a JIS A1050 aluminum plate and materials O and H18 of JIS A3005. Compositions of aluminum plates JIS A1050 and JIS A3005 are as shown in Table 1. Material O of JIS A3005 is a plate that has been softened by annealing. Material H18 of JIS A3005 is a plate that has been hardened by cold rolling without an additional heating treatment.

The abrasive slurry was applied to the surface of the aluminum plate and mechanical surface roughening was performed by rotating roller-type nylon brushes. The nylon brushes used nylon-6,10 with fiber length of 50 mm and fiber diameter of 0.48 mm. The nylon was densely mounted in holes formed in 300 mm diameter stainless steel tubes. Three brush rollers were used. There were two support rollers (diameter 200 mm) with a separation of 300 mm at a lower portion of the brush rollers. The brush rollers were pressed against the aluminum plate by a load at a drive motor which rotated the brush rollers, which load was 6 kW in excess of the load before the brush rollers were pressed against the aluminum plate. A rotation direction of the brush rollers was the same as a movement direction of the aluminum plate. The velocity of the aluminum plate was 50 m/minute. The aluminum plate was then washed with water.

(2) Etching in an Alkaline Aqueous Solution Treatment

The aluminum plate was etched by immersion in a 27% by weight aqueous solution of NaOH, containing 6.5% by weight of aluminum ions, at 60° C. An dissolution amount of the aluminum plate was 10 g/m². The aluminum plate was then subjected to a washing treatment.

(3) Desmutting Treatment

Next, the aluminum plate was desmutted by immersion for 10 seconds in a 1% by weight aqueous solution of nitric acid at 35° C. (the solution containing 0.5% by weight of aluminum ions and 0.007% by weight of ammonium ions). The aluminum plate was then subjected to a washing treatment.

(4) Electrochemical Surface Roughening Treatment in a Nitric Acid Aqueous Solution

An electrochemical surface roughening treatment was performed on the aluminum plate in a 1% by weight aqueous solution of nitric acid at 50° C. A 60 Hz trapezoid rectangular alternating current with a time TP, for current to change from zero to a peak value, of 1 ms and a duty ratio of 1:1 was used. A carbon electrode was used at a counter electrode and a ferrite was used at an auxiliary anode. Current density was 60 A/dm² when current was at the peak value, and a quantity of electricity was 65 C/dm² (total quantity of electricity for the anode duration of the aluminum plate). 5% of the current was diverted to flow from a power supply at the auxiliary electrode. The aluminum plate was then washed with water by a spray.

(5) Etching Treatment in an Alkaline Aqueous Solution

The aluminum plate was etched by immersion in a 27% by weight aqueous solution of NaOH, containing 6.5% by weight of aluminum ions, at 45° C. A dissolution amount of the aluminum plate was 4 g/m². The aluminum plate was then subjected to a washing treatment.

(6) Desmutting Treatment

Next, the aluminum plate was desmutted by immersion in a 25% by weight aqueous solution of nitric acid at 60° C. The aluminum plate was then subjected to a washing treatment.

(7) Chemical Treatment in a Hydrochloric Acid Aqueous Solution

Ink-stain originating substances were eliminated by immersing the aluminum plate for 30 seconds in a 1% by weight aqueous solution of hydrochloric acid at 60° C. The aluminum plate was then subjected to a washing treatment.

(8) Desmutting Treatment

The aluminum plate was desmutted by immersion for 40 seconds in a 25% by weight aqueous solution of nitric acid at 60° C. The aluminum plate was then subjected to a washing treatment.

(9) Anodizing Treatment

An anodizing treatment was performed in a 15% by weight aqueous solution of sulphuric acid (containing 0.5% by weight of aluminum ions) at 35° C., utilizing a direct current power supply with a current density of 2 A/dm², such that an anodization film amount was 1.1 g/m². The aluminum plate was then washed with water by a spray.

(10) Preparation of Image Forming Layer

The substrate provided was coated with the coating solution described below, and dried at 80° C. for 30 seconds. A coating amount after drying was 10 mg/m².

| Coating solution | |
|---|---|
| β-alanine | 0.10 g |
| Phenylphosphonic acid | 0.05 g |
| Methanol | 40 g |
| Pure water | 60 g |

Further, a photosensitive layer A or photosensitive layer B was provided by coating with a photosensitive solution (A) or photosensitive solution (B), described below. After drying, a photosensitive layer coating amount was 1.8 g/m², in the case of (A), or 1.0 g/m², in the case of (B).

Photosensitive solution (A)

| | |
|---|---|
| Ester compound of 1,2-diazonaphthoquinone-5-sulfonyl | 0.8 g |
| chloride and pyrogallol acetone resin (disclosed in U.S. | |
| Pat (USP) No. 3,635,709, Example 1) | |
| Binder | |
| Novolak I (see formula below) | 1.5 g |
| Novolak II (see formula below) | 0.2 g |
| Resin other than novolak III (see formula below) | 0.4 g |
| p-normal octylphenol-formaldehyde resin (disclosed in | 0.02 g |
| description of U.S. Pat No. 4,123,279) | |
| Naphthoquinone-1,2-diazide-4-sulfonic chloride | 0.01 g |
| Tetrahydrophthalic anhydride | 0.02 g |
| Benzoic acid | 0.02 g |
| Pyrogallol | 0.05 g |
| 4-[p-N,N-bis(ethoxycarbonyl methyl)aminophenyl]- | 0.07 g |
| 2,6-bis(trichloromethyl)-S-triazine | |
| Dye with 1-naphthalene sulfonate added as | 0.045 g |
| counter-anions (trade name: VICTORIA PURE BLUE | |
| BOH, produced by Hodogaya Chemical Co., Ltd.) | |
| Fluorosurfactant (trade name: F176PF, produced by Dainippon | 0.01 g |
| Ink & Chemicals, Inc.) | |
| Methyl ethyl ketone | 15 g |
| 1-methoxy-2-propanol | 10 g |

Novolak I

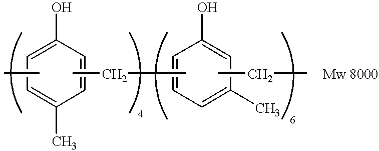

Novolak II

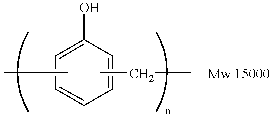

Resin III other than novolak

| | | |
|---|---|---|
| 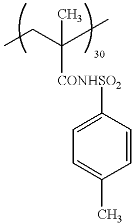 | 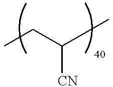 | 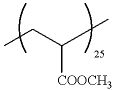 |

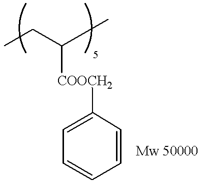

Photosensitive solution (B)

| | |
|---|---|
| m,p-cresol novolak (m:p ratio = 6:4, weight average | 1.2 g |
| molecular weight = 3500, unreacted cresol content = 0.5% | |
| by weight) | |
| Infrared absorbing agent (IR-1) (see formula below) | 0.20 g |
| VICTORIA PURE BLUE BOH dye with 1-naphthalene | 0.02 g |
| sulfonate anions as counter-ions | |
| Fluorosurfactant (trade name: MEGAFAC F177, | 0.05 g |
| produced by Dainippon Ink & Chemicals, Inc.) | |
| γ-butyrolactone | 3.0 g |
| Methyl ethyl ketone | 8.0 g |
| 1-methoxy-2-propanol | 7.0 g |
| Infrared absorbing agent (IR-1) | |

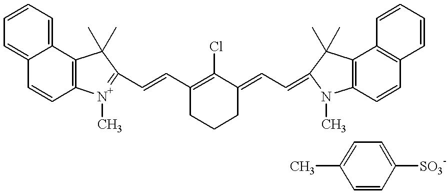

Substrate Evaluation

Mapping of Fe and Si distributions was performed on the surfaces of the aluminum substrates prepared for the Examples, using an electron probe micro-analyzer (manufacturer: JEOL Ltd., trade name: JXA-8800M) under the following conditions: accelerating voltage: 20 kV; measurement current: 1.3×10⁻⁶ A; beam diameter: 0 μm; pixels: 425×425; interval: 0.4 μm (X)×0.4 μm (Y); measurement area: 170×170 μm². A number of points where an Fe distribution (a distribution of counts of 1630 or more) and a Si distribution (a distribution of counts of 137 or more) overlapped was counted. This number of FeSi overlap points was converted to a number/mm² (the measured value ×35) and this value was rounded off. Results are shown in Table 2.

Now, results of a detailed examination of distribution states mapped by the EPMA under the above-described conditions for the aluminum substrates of Example 1 and Comparative Example 1 are presented.

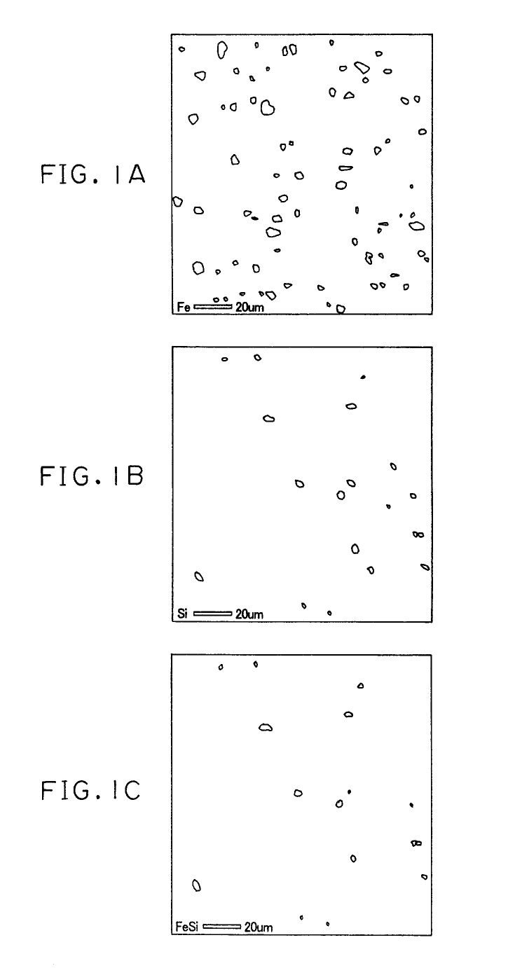

FIGS. 1A through 1C are analytical views showing the distribution state of the aluminum substrate of Example 1, mapped by the EPMA under the above-described conditions. FIG. 1A shows an Fe-only portion of a measurement range, FIG. 1B shows a Si-only portion of the measurement range and FIG. 1C shows FeSi overlap points where Fe and Si overlap. As can be clearly seen from FIG. 1C, both the surface coverage of the FeSi overlap points and the areas of individual FeSi overlap points are small. Thus, defects will tend not to occur.

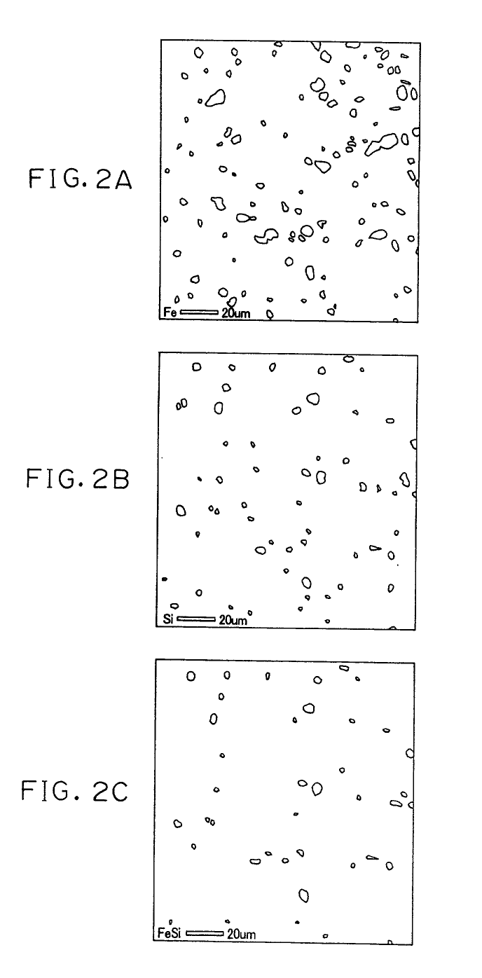

FIGS. 2A through 2C are analytical views showing the distribution state of the aluminum substrate of Comparative Example 1, mapped by the EPMA under the same conditions as for FIGS. 1A through 1C. FIG. 2A shows the Fe-only portion of the measurement range, FIG. 2B shows the Si-only portion of the measurement range and FIG. 1C shows FeSi overlap points where Fe and Si overlap. As can be clearly seen from FIG. 2C, the surface coverage of FeSi overlap points is higher than in FIG. 1C and the areas of individual FeSi overlap points are comparatively large. Thus, the surface is susceptible to the occurrence of defects.

These planographic printing plate precursors were exposed with an ultra-violet lamp and a semiconductor laser emitting infrared radiation at a wavelength of 830 nm. Then, the planographic printing plates were developed using an automatic processor (trade name: PS PROCESSOR 900VR, produced by Fuji Photo Film Co., Ltd.) stocked with a developer (trade name: DP-4, diluted by a factor of 1:6 before use) and rinsing solution (trade name: FR-3, diluted by a factor of 1:7) produced by Fuji Photo Film Co., Ltd.

After production, the obtained planographic printing plates were supplied with ink and dampening water containing chlorine ions (KCL 2%) under condition 1, a condition of severe moistness, using an actual printing press (trade name: HAMADA 900CDX, produced by Hamada Printing Press Co., Ltd.). Each planographic printing plate printed 1,000 sheets, was left idle for a time, and then printed several dozen more sheets. The latter printed sheets were visually inspected for the occurrence of stains at the non-image portion and evaluated with criteria described below. Results are shown in Table 2. Evaluations were also carried out for printing under condition 2, a condition of usual moistness (IPA: 10%, EU-3:1%).

⊚: No ink stains at all

◯: Slight ink stains; acceptable for practical purposes

◯Δ: At the lower limit of practical acceptability

Δ: Stains occur at a level unacceptable for practical purposes

X: Ink stains are extremely obvious

TABLE 2

| | | | | | | | | | Results of printing | | |
|---|---|---|---|---|---|---|---|---|---|---|---|
| | | | | | | | | | evaluation | | |
| | | Alloy | | | Hydro- | | | Number | | | Photo- |
| | | composition | | | chloric acid | FeSi | Si | of FeSi | Photosensitive | | sensitive |
| | Alloy | (%) | | | treatment | surface | surface | points | layer B | | layer A |
| | material | Fe | Si | Material | performed? | coverage (%) | coverage (%) | (/mm²) | Condition 1 | Condition 2 | Condition 1 |
| Example 1 | 1050 | 0.32 | 0.07 | H18 | Yes | 0.1 | 0.1 | 40 | ⊚ | ⊚ | ⊚ |
| Comparative | | 0.32 | 0.07 | | No | 0.8 | 1.0 | 1140 | X | X | X |
| Example 1 | | | | | | | | | | | |
| Example 2 | | 0.23 | 0.10 | | No | 0.4 | 1.0 | 800 | ◯Δ | ◯Δ | ◯Δ |
| Example 3 | | 0.23 | 0.04 | | No | 0.4 | 0.3 | 600 | ◯Δ | ◯ | ◯ |
| Example 4 | | 0.30 | 0.08 | O | Yes | 0.3 | 0.4 | 300 | ⊚ | ⊚ | ⊚ |
| Comparative | | 0.30 | 0.08 | | No | 0.6 | 0.7 | 600 | X | Δ | X |
| Example 2 | | | | | | | | | | | |
| Example 5 | 3005 | 0.50 | 0.40 | H18 | Yes | 0.2 | 0.4 | 450 | ⊚ | ⊚ | ⊚ |
| Comparative | | 0.50 | 0.40 | | No | 0.6 | 0.8 | 1270 | X | Δ | X |
| Example 3 | | | | | | | | | | | |
| Example 6 | | 0.48 | 0.37 | O | Yes | 0.3 | 0.3 | 400 | ⊚ | ⊚ | ⊚ |
| Comparative | | 0.48 | 0.37 | | No | 0.8 | 1.3 | 1490 | X | X | X |
| Example 4 | | | | | | | | | | | |

As can be clearly seen from Table 2, a planographic printing plate that uses a substrate of the present invention having few FeSi overlap points or a substrate of the present invention whose FeSi overlap point surface coverage is 0.5% or less and, moreover, whose Si surface coverage is preferably 0.6% or less, is not susceptible to staining at a non-image portion and has excellent printing characteristics. It can also be seen that a substrate having the aforementioned characteristics can be provided easily, by selection of the aluminum alloy composition and/or performance of the predetermined hydrochloric acid aqueous solution treatment.

Examples 7 to 28, Comparative Examples 5 to 14 Aluminum alloy rolled plates (aluminum plates) were fabricated for Examples and Comparative Examples respectively from two types of aluminum alloy melt having alloy compositions as shown in Table 3. These rolled plates were fabricated via a casting process and a rolling process. In the casting process, a cleaning process, which included degassing and filtration, was performed on the aluminum alloy melt. The aluminum alloy was then cast into an ingot by a DC casting method. In the rolling process, facing was performed to 10 mm on a surface of the ingot. Then, the ingot was heated without performing a soaking treatment. The ingot was heated to 400° C. and hot-rolled. During hot-rolling, alloy crystals were re-crystallized using thermo-mechanical effects of hot-rolling. Then, the alloy was cold-rolled, without annealing, to provide a rolled plate with a thickness of 0.24 mm. Flatness of this rolled plate was straightened and aluminum plates were provided respectively as Examples and Comparative Examples of the present invention.

TABLE 3

| | Fe | Si | Cu | Ti | Mn | Mg | Zn | Others |
|---|---|---|---|---|---|---|---|---|
| Composition | 0.30 | 0.08 | 0.015 | 0.03 | 0.001 | 0.001 | 0.001 | Aluminum and unavoidable |
| A | | | | | | | | impurities |
| Composition | 0.30 | 0.15 | 0.02 | 0.03 | 0.02 | 0.02 | 0.02 | Aluminum and unavoidable |
| B | | | | | | | | impurities |

(Units: % by weight)

Then, a surface roughening treatment was performed on the aluminum plates fabricated from the molten aluminum alloys having the compositions shown in Table 3, by one of the three methods shown in Table 4 (method 1, method 2 and method 3). Thus, the aluminum plates were fabricated to serve as the Examples and Comparative Examples.

TABLE 4

| | Surface roughening treatment methods | |
|---|---|---|
| Method | 1) | Brush grain (three no. 8 brushes) |
| 1 | 2) | Wash |
| | 3) | Alkali etching: 8 g/m² (25% solution of NaOH, 75° C.) |
| | 4) | Wash |
| | 5) | Desmutting with sulphuric acid (sulphuric acid: 9 g/liter, |
| | | 40° C.) |
| | 6) | Electrolytic roughening (sulphuric acid: 9 g/liter, 50° C., |
| | | quantity of electricity: 180 C/dm²) |
| Method | 1) | Alkali etching: 5 g/m² (25% solution of NaOH, 75° C.) |
| 2 | 2) | Wash |
| | 3) | Desmutting with sulphuric acid (sulphuric acid: 9 g/liter, |
| | | 40° C.) |
| | 4) | Wash |
| | 5) | Electrolytic roughening (sulphuric acid: 9 g/liter, 50° C., |
| | | quantity of electricity: 270 C/dm²) |
| Method | 1) | Brush grain (three no. 8 brushes) |
| 3 | 2) | Wash |

In Table 5, washing treatments (alkaline treatment conditions and acidic treatment conditions) performed on the aluminum plates prepared as described above are respectively shown for the Examples and the Comparative Examples. In the alkaline treatment, a pH 14 alkaline solution of caustic soda was used. In the acidic treatment, an acidic solution of sulphuric acid was used. Further, in Table 5, the concentration in acidic treatment conditions shows a concentration of sulphuric acid as measured by neutralization titration.

TABLE 5

| | | | Alkaline treatment | | Acidic treatment | | |
|---|---|---|---|---|---|---|---|
| | | Surface | conditions | | conditions | | |
| | Aluminum | roughening | Temperature | Time | Concentration | Temperature | Time |
| | material | method | (° C.) | (sec) | (g/liter) | (° C.) | (sec) |
| Example 7 | B | 1 | 65 | 4 | 170 | 65 | 4 |
| Example 8 | B | 1 | 65 | 4 | 170 | 70 | 4 |
| Example 9 | B | 1 | 65 | 4 | 170 | 80 | 4 |
| Example 10 | B | 1 | 65 | 4 | 170 | 90 | 4 |
| Example 11 | B | 1 | 65 | 4 | 400 | 65 | 4 |
| Example 12 | B | 1 | 65 | 4 | 400 | 70 | 4 |
| Example 13 | B | 1 | 65 | 4 | 400 | 80 | 4 |
| Example 14 | B | 1 | 65 | 4 | 400 | 90 | 4 |
| Example 15 | B | 1 | 65 | 4 | 500 | 65 | 4 |
| Example 16 | B | 1 | 65 | 4 | 500 | 70 | 4 |
| Example 17 | B | 1 | 65 | 4 | 500 | 80 | 4 |
| Example 18 | B | 1 | 65 | 4 | 500 | 90 | 4 |
| Example 19 | B | 1 | 65 | 4 | 800 | 65 | 4 |
| Example 20 | B | 1 | 65 | 4 | 800 | 70 | 4 |
| Example 21 | B | 1 | 65 | 4 | 800 | 80 | 4 |
| Example 22 | B | 1 | 65 | 4 | 800 | 90 | 4 |
| Example 23 | A | 1 | 65 | 4 | 400 | 65 | 4 |
| Example 24 | A | 1 | 65 | 4 | 400 | 70 | 4 |
| Example 25 | A | 1 | 65 | 4 | 400 | 80 | 4 |
| Example 26 | A | 1 | 65 | 4 | 400 | 90 | 4 |
| Example 27 | B | 2 | 65 | 4 | 400 | 80 | 4 |
| Example 28 | B | 3 | 65 | 4 | 400 | 80 | 4 |
| Comparative | B | 1 | 65 | 4 | 140 | 65 | 4 |
| Example 5 | | | | | | | |
| Comparative | B | 1 | 65 | 4 | 140 | 70 | 4 |
| Example 6 | | | | | | | |
| Comparative | B | 1 | 65 | 4 | 140 | 80 | 4 |
| Example 7 | | | | | | | |
| Comparative | B | 1 | 65 | 4 | 140 | 90 | 4 |
| Example 8 | | | | | | | |
| Comparative | B | 1 | 65 | 4 | 400 | 30 | 4 |
| Example 9 | | | | | | | |
| Comparative | B | 1 | 65 | 4 | 400 | 50 | 4 |
| Example 10 | | | | | | | |
| Comparative | B | 1 | 65 | 4 | 400 | 60 | 4 |
| Example 11 | | | | | | | |
| Comparative | B | 2 | 65 | 4 | 400 | 50 | 4 |
| Example 12 | | | | | | | |
| Comparative | B | 3 | 65 | 4 | 400 | 50 | 4 |
| Example 13 | | | | | | | |
| Comparative | A | 1 | 65 | 4 | 400 | 60 | 4 |
| Example 14 | | | | | | | |

In the acidic treatments relating to the Comparative Examples, the underlined values fall outside the ranges specified for the alkaline treatment and acidic treatment conditions of the present invention.

The aluminum plates (substrates for planographic printing plates) prepared in accordance with the above-described conditions of Examples 7 through 28 and Comparative Examples 5 through 14 were coated with a photosensitive material having the below-described composition, such that a coating amount after drying was 1.5 g/m². Thus, a photosensitive layer was provided on each aluminum plate and planographic printing plate precursors were provided.

Photosensitive material composition

| | |
|---|---|
| Ester compound of naphthoquinone-1,2-diazide-5- | 0.75 g |
| sulfonyl chloride and pyrogallol acetone resin (disclosed | |
| in U.S. Pat. No. 3,635,709, Example 1) | |
| Cresol novolak resin | 2.00 g |
| OIL BLUE #603 (trade name, produced by Orient | 0.04 g |
| Chemical Co., Ltd.) | |
| Ethylene dichloride | 16 g |
| 2-methoxy ethyl acetate | 12 g |

The thus prepared planographic printing plate precursors were exposed for 50 seconds in a vacuum printing frame by a 3 kW metal halide lamp at a distance of 1 metre radiating through a transparent positive film. Then the planographic printing plates were developed in a 5.26% aqueous solution of sodium silicate with a SiO₂/Na₂O mole ratio of 1.74 (pH=12.7). And then printing tests were performed with the planographic printing plates of Examples 7 through 28 and Comparative Examples 5 through 14. A printing press used was a HAMADA 900CDX (trade name). First, 1,000 sheets of printing paper were printed continuously. Then, the planographic printing plate was left to dry while still mounted in the printing press. This cycle of printing and leaving to dry was repeated, thereby forcefully creating a situation in which staining was likely to occur at the non-image portion. The occurrence of staining at non-image areas of the images printed on the printing paper was evaluated. At this time, evaluation was performed by evaluating the printed images according to a 10-level relative evaluation scale, with 10 points being excellent and 5 points being the lower limit of practical acceptability. Evaluation results are shown in Table 6.

TABLE 6

| | Excessive Ink |
|---|---|
| | staining evaluation |
| Example 7 | 6 |
| Example 8 | 7 |
| Example 9 | 9 |
| Example 10 | 9 |
| Example 11 | 7 |
| Example 12 | 9 |
| Example 13 | 10 |
| Example 14 | 10 |
| Example 15 | 8 |
| Example 16 | 9 |
| Example 17 | 10 |
| Example 18 | 10 |
| Example 19 | 9 |
| Example 20 | 10 |
| Example 21 | 10 |
| Example 22 | 10 |
| Example 23 | 8 |
| Example 24 | 10 |
| Example 25 | 10 |
| Example 26 | 10 |
| Example 27 | 10 |
| Example 28 | 10 |
| Comparative Example 5 | 2 |
| Comparative Example 6 | 3 |
| Comparative Example 7 | 4 |
| Comparative Example 8 | 4 |
| Comparative Example 9 | 1 |
| Comparative Example 10 | 4 |
| Comparative Example 11 | 4 |
| Comparative Example 12 | 4 |
| Comparative Example 13 | 4 |
| Comparative Example 14 | 4 |

As can be clearly seen from the evaluations shown in Table 6, the planographic printing plates having as substrates thereof aluminum plates prepared in accordance with the conditions of Examples 7 through 28 all had ink staining factors better than 5 and were therefore all superior. A trend can also be seen for Examples 7 to 22 in that as the acid treatment temperature was raised above 65° C., the excessive ink staining factor was improved.

Furthermore, the excessive ink staining factor was improved by the planographic printing plate substrate fabrication method of these Examples irrespective of variations in surface roughening conditions, as shown in Table 3 (refer to Examples 13, 27 and 28, and Comparative Examples 10, 12 and 13). Moreover, it can be seen that, although amounts of impurity elements had a slight effect, excessive ink staining was not a problem regardless of the compositions of the aluminum alloys (refer to Examples 11 to 14 and 23 to 26, and Comparative Examples 11 and 14). With regard to intermetallic compounds, when the surfaces of the aluminum plates (the planographic printing plate substrates fabricated in accordance with the Examples and Comparative Examples) were examined with a scanning electron microscope (SEM), it was seen that, while particles of intermetallic compounds were scattered over the surfaces of the Comparative Example aluminum plates, there were much fewer particles of intermetallic compounds at the surfaces of the Example aluminum plates.

In the Examples, an aqueous solution whose principal component was sulphuric acid was used as the acidic aqueous solution. However, the same effects can, of course, be obtained using nitric acid, hydrochloric acid, etc., or a mixture of acids. However, in view of preventing corrosion of equipment, sulphuric acid is more preferable than nitric acid or hydrochloric acid. Also, the specified conditions for the alkaline treatment in the Examples were a solution temperature of 65° C. and a duration of 4 seconds, but it has been confirmed that, provided the duration is adjusted in response to the solution temperature, the same effects as with a solution temperature of 65° C. can be obtained with any solution temperature in the range 60° C. to 80° C. In view of productivity, it is desirable if the solution temperature is 65° C. or higher because the treatment can be performed in a shorter time. Temperatures above 80° C. are unpreferable because controlling dissolution quantities becomes difficult.

In accordance with the present invention, a planographic printing plate substrate which, regardless of printing conditions, has excellent printing characteristics and does not stain at a non-image portion, and a method of fabricating the substrate can be provided.

What is claimed is:

1. A substrate for a planographic printing plate, wherein the substrate is one of aluminum and an aluminum alloy, a surface of the substrate is subjected to a surface roughening treatment and an anodizing treatment, and a surface coverage of overlap points of macularly distributed Fe and Si is at most 0.5%, as determined by binarizing specific count values for Fe and Si at examination with an electron probe micro-analyzer under conditions of: an acceleration voltage of 20 kV; a measurement current of 1.3×10⁻⁶ A; a beam diameter of 0 μm; 425×425 pixels; intervals of 0.4 μm in both an X direction and a Y direction; a measurement area of 170×170 μm²; a threshold count value for Fe of 1630; and a threshold count value for Si of 137.

2. The substrate of claim 1, wherein a surface coverage of macularly distributed Si is at most 0.6%, as determined by examination of the surface of the substrate with the electron probe micro-analyzer under the conditions recited in claim 1.

3. A substrate for a planographic printing plate, wherein the substrate is one of aluminum and an aluminum alloy, a surface of the substrate is subjected to a surface roughening treatment and an anodizing treatment, and, of overlap points of macularly distributed Fe and Si, there are at most 800 overlap points larger than 1.6×10⁻⁷ mm² per 1 mm², as determined by binarizing specific count values for Fe and Si during examination with an electron probe micro-analyzer under conditions of: an acceleration voltage of 20 kV; a measurement current of 1.3×10⁻⁶ A; a beam diameter of 0 μm; 425×425 pixels; intervals of 0.4 μm in both an X direction and a Y direction; a measurement area of 170×170 μm²; a threshold count value for Fe of 1630; and a threshold count value for Si of 137.

4. A method of fabricating a substrate for a planographic printing plate, the method comprising the steps of:
(1) performing a surface roughening treatment on an aluminum alloy;
(2) washing the aluminum alloy in an alkali solution having a pH of at least 10 and a temperature of 60 to 80° C.;
(3) washing the aluminum alloy in an acidic solution having an acid concentration of 170 to 800 g/liter as measured by neutralization titration and a temperature of 65 to 90° C.; and
(4) performing an anodizing treatment on a surface of the aluminum alloy.

5. The method of claim 4, wherein a fluid having sulphuric acid as a principal component thereof is used as the acidic solution in which the aluminum alloy is washed.
